(19) United States
(12) Patent Application Publication
(10) Pub. No.: US 2008/0268136 A1
(43) Pub. Date: Oct. 30, 2008

(54) METHOD OF PRODUCING ORGANIC LIGHT EMITTING APPARATUS

(75) Inventors: Yuzo Tokunaga, Yokohama-shi (JP); Manabu Otsuka, Yokohama-shi (JP); Seiji Mashimo, Yokohama-shi (JP); Taro Endo, Kawasaki-shi (JP); Naoya Nishida, Chigasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/107,815

(22) Filed: Apr. 23, 2008

(30) Foreign Application Priority Data
Apr. 27, 2007 (JP) 2007-118217
Mar. 7, 2008 (JP) 2008-057471

(51) Int. Cl. B05D 5/12

(52) U.S. Cl. 427/66

(57) ABSTRACT

There is provided a method of producing an organic light emitting apparatus including a substrate, an organic light emitting device formed on the substrate, and a device separating film formed on a periphery of the organic light emitting device, the organic light emitting device including a lower electrode, an organic compound layer, and an upper electrode from the substrate side in the stated order, includes: cleaning a substrate having at least the lower electrode and the device separating film formed thereon by irradiating the substrate with UV-light while introducing gas containing at least oxygen in an atmosphere and exhausting the gas under a pressure in a range of 10 Pa or more to 10,000 Pa or less; forming an organic compound layer on the cleaned lower electrode; and forming an upper electrode on the organic compound layer.

### BACKGROUND OF THE INVENTION

1. Field of the Invention

The present invention relates to a method of producing an organic light emitting apparatus that can be used for an image display apparatus, a lighting system, and the like.

2. Description of the Related Art

In 1987, Tang et al. has proposed an organic light emitting device (organic EL (electroluminescence) device) having a configuration in which organic compounds with different carrier transportabilities are laminated, and holes and electrons are injected from anodes and cathodes with good balance, respectively. Specifically, the device produced by setting a thickness of an organic compound layer (organic EL layer) to be 200 nm or less has achieved an efficiency and a luminance of 1,000 cd/m² at a voltage of 10 V, which have not been achieved up to now.

After that, an attempt has been made so as to obtain high luminance light emission at a lower voltage until now. For example, Japanese Patent Application Laid-Open No. H07-142168 discloses that an ITO anode is subjected to UV treatment or plasma treatment as the treatment before the formation of an organic EL layer, whereby a light emitting threshold value decreases to enhance current properties, and the degradation in light emitting properties with time is suppressed.

Japanese Patent No. 3,704,883 discloses that the process of forming an anode substrate, the treatment before the formation of an organic EL layer, the formation of an organic EL layer, and the formation of a cathode are performed under a reduced pressure consistently. More specifically, the patterning of an anode is performed by dry etching, and UV ozone treatment and oxygen plasma treatment are continuously performed under a reduced pressure consistently, whereby the surface of an anode becomes clean, the anode is oxidized appropriately to enhance a hole injection property, the light emission is made uniform, the driving voltage is decreased, and the life is prolonged.

Japanese Patent Application Laid-Open No. H11-045779 discloses a technology including performing the treatment before the formation of an organic EL layer by cleaning an anode substrate by ozone with an ozonizer under reduced pressure without using UV-light or plasma.

Japanese Patent No. 3,394,130 discloses a technology including irradiating a substrate with UV-light having directivity under a reduced pressure of to 0.1 Pa, and transporting a substrate to an organic EL layer formation chamber with a higher ambient pressure to form an organic EL layer, thereby preventing the substrate from being contaminated in a chamber of the treatment before the formation of the organic EL layer.

Japanese Patent Application Laid-Open No. 2000-353593 describes that a first electrode on a substrate side is formed and is irradiated with UV-light from a UV-light lamp in the presence of oxygen and nitrogen, whereby a substrate with a first electrode is cleaned. It is described that it is preferred to adjust the pressure in a cleaning chamber to be 4.00 Pa to an ambient pressure during cleaning. It is also described as an example that a partition wall is formed using a negative photoresist, oxygen and nitrogen are introduced after that, and a substrate with an electrode is cleaned under an ambient pressure.

In an organic EL device used in a light emitting apparatus, in order to define a light emitting area and a shape of an electrode on a substrate side, and in order to enable independent light emission of a pixel, a device separating film mainly including a resin material and an inorganic material is generally formed. Such a device separating film is formed generally by forming an electrode on a substrate side (lower electrode) to be an anode or a cathode, and then by uniformly applying a resin material, an inorganic material, or a precursor thereof on the surface of the electrode, or by using a film formation method such as CVD. After that, the device separating film is processed using a photoresist method or the like so that an electrode on a substrate side to be a pixel electrode is exposed.

In an organic EL device having a device separating film, sufficient driving durability characteristics may not be obtained, and a light emission state may become nonuniform after the device is left under high temperature and high humidity in some cases. This is considered to be caused by the residue of a device separating film material or a resist material used in a photoresist process on an exposed pixel electrode during the formation of the above-mentioned device separating film, and caused by the moisture stored in the device separating film.

Further, the device separating film is decomposed by the above-mentioned UV treatment or plasma treatment, and the decomposed substance is also considered to cause the above problem by adhering to the surface of a pixel electrode. That is, there has been no technology for a treatment before the formation of an organic EL layer, in which a substrate with an electrode and a device separating film formed thereon is cleaned efficiently, and sufficient driving durability characteristics and leaving durability characteristics are satisfied.

In the above Japanese Patent No. 3,704,883, the patterning of an anode is performed by dry etching, and the UV ozone treatment and oxygen plasma treatment are consistently performed under a reduced pressure, whereby the surface of the anode becomes clean, and the anode is oxidized appropriately to enhance a hole injection property. Further, as a method of cleaning with UV ozone, oxygen gas is introduced from a high-vacuum state so that a pressure of 0.01 torr (about 1.33 Pa) or more is obtained, and UV-light is irradiated.

However, according to such a method, a device separating film cannot be formed, or a material to be used and the like need to be limited strictly, so an organic EL device to be a high-quality light emitting apparatus cannot be achieved.

Japanese Patent Application Laid-Open No. H11-045779 uses a method including cleaning the surface of a pixel electrode with ozone by an ozonizer without using UV-light. However, according to this method, because the effect of cutting an intermolecular bond with UV energy is not obtained, so the decomposition of a contaminant and a residue does not proceed sufficiently. Consequently, excellent driving durability characteristics cannot be obtained.

The above Japanese Patent No. 3,394,130 uses a method including irradiating UV-light having directivity under a reduced pressure of 0.0001 to 0.1 Pa. However, a required amount of ozone and active oxygen cannot be generated in this pressure range, and excellent driving durability characteristics cannot be satisfied.

In the above Japanese Patent Application Laid-Open No. 2000-353593, it is preferred that the pressure in a cleaning chamber be 4.00 Pa to ambient pressure, and the irradiation is conducted under an ambient pressure in examples. However, under an ambient pressure, a contaminant and a residue remaining on the surface of an electrode further increase, which may rather degrade a state compared with the state before cleaning. Further, according to an experiment conducted by the inventors, it was found that a pressure of 4.00 was too low to generate a required amount of ozone and active oxygen, and excellent driving durability characteristics could not be obtained.

### SUMMARY OF THE INVENTION

The present invention provides a method of producing an organic light emitting apparatus that satisfies excellent driving durability characteristics and leaving-degradation durability characteristics.

In order to achieve the above-mentioned object, the present invention provides a method of producing an organic light emitting apparatus including a substrate, an organic light emitting device formed on the substrate, and a device separating film formed on a periphery of the organic light emitting device, the organic light emitting device including a lower electrode, an organic compound layer, and an upper electrode from the substrate side in the stated order, the method including: cleaning a substrate having at least the lower electrode and the device separating film formed thereon by irradiating the substrate with UV-light while introducing gas containing at least oxygen in an atmosphere and exhausting the gas under a pressure in a range of 10 Pa or more to 10,000 Pa or less; forming an organic compound layer on the cleaned lower electrode; and forming an upper electrode on the organic compound layer.

According to the present invention, the substrate with at least a lower electrode and a device separating film formed thereon is irradiated with UV-light while gas containing at least oxygen is being introduced into an atmosphere and exhausted under a pressure in a range of 10 Pa or more to 10,000 Pa or less. Thus, excellent driving durability characteristics and leaving durability characteristics are obtained.

Specifically, residues of a device separating film material and a resist material and other contaminants remaining on a lower electrode are decomposed with energy of UV-light by irradiation of UV-light under a reduced pressure of 10 Pa or more to 10,000 Pa or less. Further, the residues and contaminants are removed efficiently with the action of ozone and active oxygen generated by UV-light and oxygen, and the removal function of the reduced ambient pressure. Owing to this, durability of the injection of a hole and an electron into an organic EL layer from a lower electrode is maintained, which remarkably enhances driving durability characteristics.

Further, even in the case where a device separating film stores moisture, the surface of the device separating film is decomposed in a slight amount with UV-light, and moisture is efficiently diffused in an atmosphere due to the reduced ambient pressure. Thus, the non-uniformity of a light emission state that is likely to occur after an apparatus is left under high-temperature and high-humidity is dramatically eliminated. Further, the problem that the decomposed device separating film material adheres to the surface of the lower electrode is unlikely to arise, since the ambient pressure is in a range of 10 Pa or more to Pa or less.

Further features of the present invention will become apparent from the following description of exemplary embodiments with reference to the attached drawings.

### BRIEF DESCRIPTION OF THE DRAWINGS

FIG. 1 is a schematic view illustrating a typical partial cross-sectional structure of an organic light emitting apparatus according to the present invention.

FIG. 2 is a schematic view of a substrate pre-treatment apparatus.

FIG. 3 is a production flow and a diagram illustrating a change in pressure in each process of the organic light emitting apparatus according to an example of the present invention.

### DESCRIPTION OF THE EMBODIMENTS

A method of producing an organic light emitting apparatus according to the present invention is suitably performed as a method of producing an organic light emitting apparatus including a substrate, an organic light emitting device formed on the substrate, and a device separating film formed on the periphery of the organic light emitting device. The organic light emitting device in the present invention includes a lower electrode, an organic compound layer (organic EL layer), and an upper electrode in the order from the substrate side in the same way as in an ordinary organic light emitting device.

The production method includes a cleaning process (pre-treatment process) of irradiating a substrate, on which at least the above lower electrode and the above device separating film are formed, with UV-light while gas containing at least oxygen is being introduced into and exhausted from an atmosphere under a pressure in a range of 10 Pa or more to 10,000 Pa or less. Further, the production method includes the process of forming an organic compound layer on a lower electrode of the cleaned substrate, and the process of forming an upper electrode on the organic compound layer.

Conventionally, baking treatment is generally performed under vacuum so as to remove moisture (dehydration) from a device separating film before forming an organic EL layer after forming the device separating film. Then, after dehydration, an organic EL layer is generally formed while a vacuum state is maintained so that moisture does not return to the device separating film again.

However, according to the present invention, the surface of a lower electrode is cleaned through the irradiation of UV-light while gas containing oxygen is introduced into and exhausted from an atmosphere under a reduced pressure environment of 10 Pa or more to 10,000 Pa or less that is higher than vacuum after vacuum baking is performed. Then, an organic EL layer is formed under vacuum after cleaning, whereby satisfactory light emitting characteristics can be obtained. The vacuum in the present invention refers to the range of a pressure of 10⁻⁶ Pa or more to 10⁻² Pa or less.

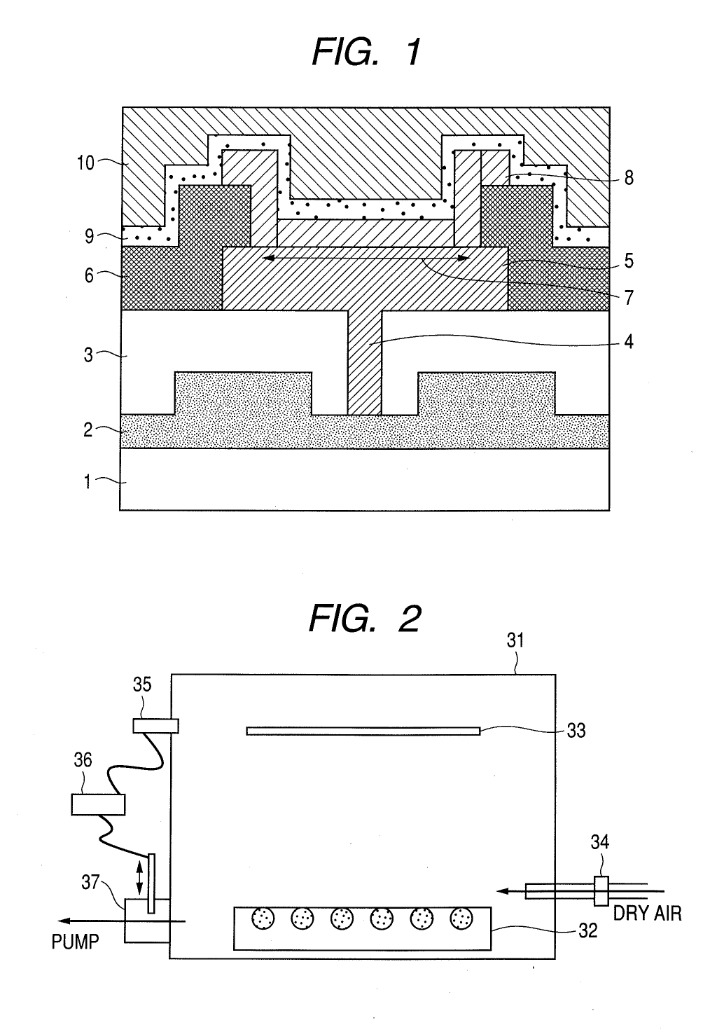

Hereinafter, a configuration and a production process of an organic light emitting apparatus will be described with reference to FIG. 1. FIG. 1 is a view schematically illustrating a cross-section of one organic light emitting device constituting the organic light emitting apparatus of the present invention.

A thin film transistor (TFT) 2 is arrayed and formed on a substrate 1 including glass, silicon, or a plastic film so as to correspond to each pixel. If an organic light emitting device is of a top-emission type, the substrate 1 does not need to have light transparency.

On the substrate 1, an inter-layer insulating film 3 was provided so as to cover the TFT 2, and the inter-layer insulating film 3 was provided with a connection hole 4 reaching the wiring (not illustrated) to the TFT 2. As the inter-layer insulating film 3, an inorganic material film including silicon oxide (SiO₂) or silicon nitride (Si₃N₄) may be used; however, it is desired to flatten the film surface by burying unevenness of the TFT and the wiring portion, so an acrylic resin film is generally provided in a thickness of several to several tens of μm.

A lower electrode 5 connected to the wiring via the connection hole 4 is patterned so as to correspond to each pixel (organic light emitting device) on the inter-layer insulating film 3. The lower electrode 5 is used, for example, as an anode of an organic light emitting device. Therefore, if the organic light emitting device is of a top-emission type, a material with a high reflectivity such as Cr, Ag, Al, or an alloy thereof with other metal is used. In order to enhance an injection efficiency of a charge, it is also possible to laminate a conductive oxide film including ITO or IZO. In the case of a lower surface light emitting type, ITO, IZO, or the like is used.

Treatment before forming an organic EL layer that is the feature of the present invention can be used optimally for an organic light emitting device in which a substrate-side electrode (lower electrode 5) is an anode so as to enhance a work function. However, even in the case where a substrate-side electrode is a cathode, the effects are obtained.

On the inter-layer insulating film 3, a device separating film 6 is provided so as to cover the periphery of the lower electrode 5. The device separating film 6 includes an opening portion 7 patterned so as to expose only the surface of the lower electrode 5. The opening portion 7 functions substantially as a light emitting portion in the organic light emitting device.

As the device separating film 6, a resin material film including photosensitive polyimide, an acrylic resin, or the like, or an inorganic material film including silicon oxide (SiO₂) or silicon nitride (SiN) is suitably used.

Thus, it is desired that a substrate (device substrate) with at least the lower electrode 5 and the device separating film 6 formed thereon is produced, subjected to wet-cleaning with various solvents, a surfactant, pure water, or the like, and subjected to dehydration by heating at about 100° C. to 200° C. under vacuum.

After the dehydration by heating, a pre-treatment process that is the feature of the present invention was conducted immediately before the formation of an organic EL layer (organic compound layer) 8. Specifically, in a substrate pre-treatment apparatus connected to a vacuum vapor deposition apparatus for forming the organic EL layer 8, the above device substrate was treated.

FIG. 2 is a simple view illustrating a substrate pre-treatment apparatus in the present invention. Reference numeral 31 denotes a vacuum tank, reference numeral 32 denotes a UV-lamp, reference numeral 33 denotes a substrate (device substrate), reference numeral 34 denotes a mass-flow controller, reference numeral 35 denotes a vacuum gauge, reference numeral 36 denotes a pressure controller, and reference numeral 37 denotes a variable valve.

The substrate pre-treatment apparatus includes a dry pump that is devised for ozone resistance by being connected to the variable valve 37 whose opening portion can be adjusted and a turbo molecular pump that can exhaust under high vacuum. The pressure controller 36 adjusts the opening portion of the variable valve 37 based on the vacuum gauge 35. The substrate 33 is subjected to UV-ozone treatment with the UV-lamp 32 by regulating an ambient pressure while gas such as dry air and oxygen is being introduced with these mechanisms and the mass-flow controller 34.

It is desired that gas such as dry air and oxygen to be introduced contains moisture as less as possible, and gas with a dew point of −70° C. or less is used suitably.

As the UV irradiation source (lamp) 32, a low-pressure mercury lamp and an excimer lamp can be used. While gas containing at least oxygen is being introduced in a range of 0.1 slm to 500 slm, and an ambient pressure is being controlled in a range of 10 Pa or more to 10,000 Pa or less, the substrate 33 is irradiated with UV light for 0.5 minutes to 60 minutes. The distance between the substrate 33 and the UV-lamp 32 is desirably in a range of 1 mm to 50 mm, and in order to make the irradiation intensity uniform, it is desired that the substrate 33 or the UV-lamp 32 is shaken. After the irradiation of UV-light for a predetermined time or while UV-light is being radiated, the introduction of gas is stopped, and the substrate pre-treatment apparatus is exhausted to reach a high vacuum of 10⁻³ Pa or less. After that, the substrate 33 is transported to the vacuum vapor deposition apparatus rapidly while the high vacuum atmosphere is maintained.

In the case where the ambient pressure is less than 10 Pa, even if oxygen is introduced in the atmosphere and exhausted, the amount of ozone and active oxygen required for removing a decomposed substance of a contaminant and a residue on the surface of the lower electrode 5 is insufficient. Therefore, excellent driving durability characteristics cannot be satisfied, and the injection of carriers from the lower electrode 5 to the organic EL layer 8 is inhibited remarkably.

Further, in the case where the ambient pressure is larger than 10,000 Pa, a contaminant and a residue remaining on the surface of the lower electrode 5 increases more, driving durability characteristics are degraded, moisture stored in the device separating film 6 is unlikely to be diffused in the atmosphere, and leaving-degradation durability characteristics may be degraded particularly under high-temperature and high-moisture.

After the treatment before the formation of the organic EL layer, an organic EL layer 8 is formed on the transported device substrate, mainly using vacuum heating vapor deposition. As a method of forming the organic EL layer 8, EB vapor deposition, an LB method, spin-coating, an ink-jet method, a thermal transfer method, or the like can be used in addition to the vacuum heating vapor deposition. The organic EL layer 8 is obtained by successively laminating, for example, a hole transporting layer, a light emitting layer, an electron transporting layer, an electron injecting layer, and the like.

In the case of forming an organic EL layer under vacuum as in the vacuum heating vapor deposition, generally, the processes from the dehydration by heating of a substrate to the following sealing process are performed consistently under vacuum. Thus, the influence of the atmosphere on the organic EL layer can be minimized. However, according to the present invention, by increasing the pressure more than the vacuum during the process of substrate pre-treatment, and cleaning the substrate under reduced pressure of 10 Pa or more to 10,000 Pa or less, the driving durability characteristics and the leaving-degradation durability characteristics of the organic light emitting device could be enhanced remarkably.

Next, an upper electrode (cathode) 9 is provided so as to cover the organic EL layer 8. The upper electrode 9 is provided as one layer [[on]] above the substrate 1 as an electrode common to each pixel. In the case of a top-emission type, the upper electrode 9 has light permeability. Generally, a conductive oxide film including ITO, IZO, or the like is used. In the case of a lower surface light emitting type, the upper electrode 9 is a reflective electrode, and Al, Ag, or an alloy thereof with another metal is used suitably.

Further, in order to prevent the penetration of moisture to the organic EL layer 8, the organic light emitting device is sealed. A transparent protective film 10 including an inorganic material film such as silicon oxide or silicon nitride, or a polymer film may be provided to seal the organic light emitting device. In this case, the processes up to the process of sealing after the formation of the organic EL layer are suitably performed under vacuum. Further/alternatively, the organic light emitting device may be sealed with a cap material such as a glass plate. In this case, it is preferred that inactive gas such as nitrogen is sealed in a gap formed between the cap material and the organic light emitting device, and in this case, the organic light emitting device is released from vacuum before the sealing process.

In the above embodiment, one organic light emitting device is provided on the substrate. However, the present invention is applicable to a display apparatus in which a plurality of organic light emitting devices are arranged on the substrate, each of which forms a pixel. The driving of the plurality of organic light emitting devices may be of an active matrix type in which each pixel includes a switching element controlling light emission of each light emitting device, or may be of a passive matrix type in which a light emitting device is formed at an intersection of stripe-shaped electrodes.

An organic light emitting apparatus produced by the production method of the present invention can be used for display portions of various electronic appliances, light emitting portions of lighting systems, and the like. Examples of the electronic appliances include a television, a personal computer, a digital camera, a mobile telephone, a mobile music playing apparatus, a personal digital assistant (PDA), and a car navigation system.

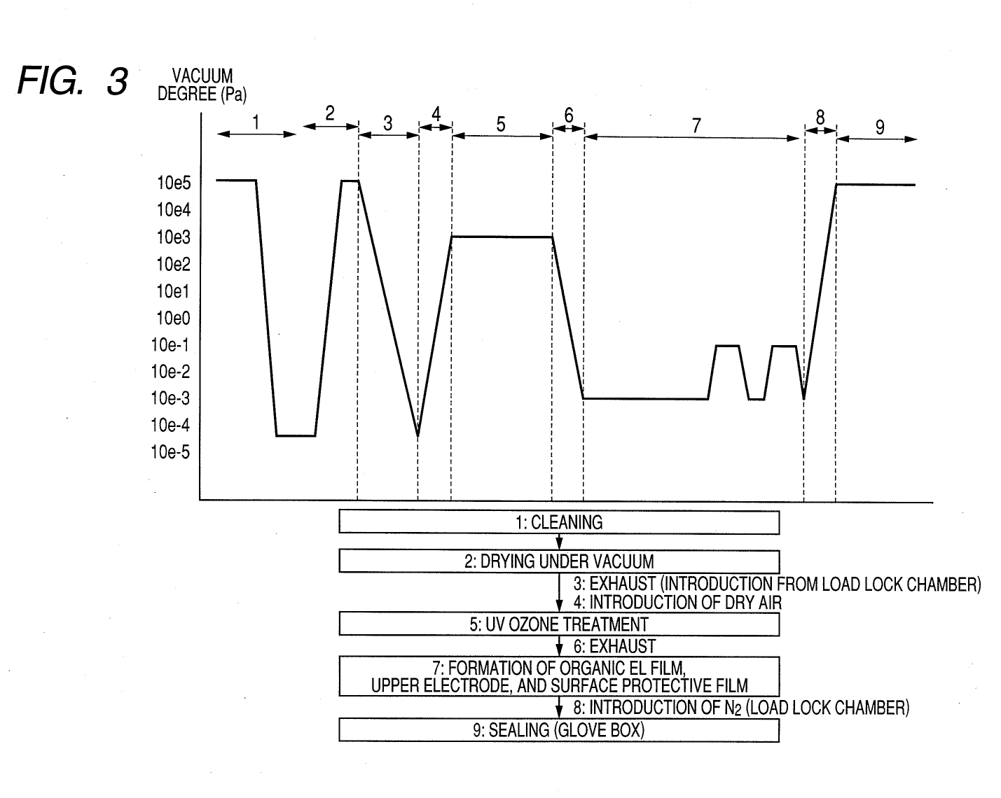

Hereinafter, a method of producing an organic light emitting apparatus according to the present invention will be described by way of examples and results thereof. Further, Table 1 summarizes setting conditions and results of examples and comparative examples. Further, FIG. 3 illustrates a production flow of the organic light emitting apparatus in the examples, and a change in pressure in each process.

### Example 1

A device separating film with a thickness of 2 μm was formed over the entire surface of a substrate on which an ITO film (thickness: 60 nm) formed on an Ag alloy film (thickness: 100 nm) was provided as an anode (lower electrode) using a positive photosensitive polyimide resin. Next, the device separating film was patterned by exposure to light with a UV-lamp, followed by developing, whereby an opening portion was formed.

The device substrate thus obtained was cleaned with an aqueous solution of a surfactant, and rinsed with ion exchanged water and an ultrasonic wave.

The cleaned device substrate was placed in a vacuum drier, whereby dehydration was conducted at 200° C. for 24 hours.

The device substrate subjected to dehydration was introduced in a substrate pre-treatment apparatus, opposed to a low-pressure mercury lamp (output: 110 W), and shaken at a rate of 20 mm/sec. in a range of an interval of 50 mm. The shortest distance between the lamp and the substrate was 5 mm. The substrate pre-treatment apparatus was exhausted to obtain a high vacuum state of 5×10⁻⁵ Pa, and thereafter, dry air having a dew point of −80° C. was introduced into the substrate pre-treatment apparatus at a flow rate of 10 slm. When the pressure in the substrate pre-treatment apparatus reached 1,000 Pa, the balance of an exhaust pressure was taken with a pressure controller while the dry air was being introduced, whereby the pressure in the substrate pre-treatment apparatus was kept at 1,000 Pa.

In this state, the device substrate was irradiated with UV-light to be subjected to UV ozone treatment for 10 minutes.

After the elapse of 10 minutes, the irradiation of UV-light was stopped to suspend the introduction of the dry air, whereby the substrate pre-treatment apparatus was exhausted.

When the pressure in the substrate pre-treatment apparatus reached 1×10⁻³ Pa, the device substrate was transported to an organic EL layer vapor deposition chamber of a vacuum vapor deposition apparatus maintained at 1×10⁻⁵ to 5×10⁴ Pa, and an organic EL layer, an upper electrode, and a protective film were laminated successively through the subsequent process.

N,N-α-dinaphthylbenzidine (α-NPD) was subjected to vacuum-deposition to have a thickness of 40 nm on the anode exposed from the opening portion, whereby a hole transporting layer was formed. Then, a codeposited film of cumarin 6 (1.0 vol %) and tris[8-hydroxyquinolinate]aluminum (Alq3) was formed to have a thickness of 30 nm, whereby a light emitting layer was formed. Next, as an electron transporting layer, tris[8-hydroxyquinolinate]aluminum (Alq3) was formed to have a thickness of 10 nm. Further, a codeposited film of cesium carbonate (0.7 vol %) and tris[8-hydroxyquinolinate]aluminum (Alq₃) was formed to a thickness of 40 nm, whereby an electron injecting layer was formed. Each layer corresponds to an organic EL layer.

Then, the substrate was transported to a sputtering chamber of the vacuum vapor deposition apparatus, and an indium tin oxide (ITO) was formed into a film having a thickness of 220 nm under a pressure of 0.6 Pa while Ar gas was being introduced (100 sccm) by sputtering, whereby a cathode 9 was formed. Further, oxygen gas (0.2 sccm) and nitrogen gas (10 sccm) were introduced and a silicon (Si) target was subjected to reactive sputtering under a pressure of 0.6 Pa, whereby a transparent oxynitride silicon film (Si—O—N film) was formed to have a thickness of 500 nm, whereby a surface protective film 10 was formed. After that, the substrate whose film formation process was completed was transferred to a glove box, and the glove box was sealed with a glass cap containing a drying agent in a nitrogen atmosphere.

The organic light emitting device (emitting green light) of the organic light emitting apparatus obtained through the above production procedure was lighted continuously at a constant current for 100 hours at a current value of 100 A/cm², and an initial luminance and a luminance after 100 hours were measured with a luminance meter (BM-7 manufactured by Topcon Corporation), whereby a change in light emitting characteristics was evaluated. A luminance change L (100 h)/L (ini) was 95.0% (initial luminance L (ini)=1,300 cd/m²), and excellent drive and life characteristics were obtained.

Then, the organic light emitting apparatus was placed in a thermal hygrostat tank at a temperature of 80° C. and a humidity of 80%, whereby a leaving evaluation for 1,000 hours was conducted. When the light emission state after leaving was observed, it was found that green light was emitted uniformly as in the case of before leaving.

### Example 2

A device substrate was produced in the same way as in Example 1 except for using a Cr film having a thickness of 100 nm as an anode, followed by cleaning and dehydration. Further, as treatment before the formation of an organic EL layer, UV ozone treatment was conducted in the same way as in Example 1 except for setting an ambient pressure to be 100 Pa.

The obtained organic light emitting apparatus was evaluated in the same way as in Example 1 to find that L(100 h)/L(ini) was 94.5% (initial luminance L (ini)=1,050 cd/m²) and the organic light emitting apparatus had excellent drive and life characteristics as the same as Example 1. Further, the light emission state after leaving at a temperature of 80° C. and a humidity of 80% for 1,000 hours was the same as in the case of before leaving.

### Example 3

An organic light emitting apparatus was produced in the same way as in Example 1 using the device substrate used in Example 1 as it was except that the pressure during the treatment before the formation of an organic EL layer was 10,000 Pa.

The obtained organic light emitting apparatus was evaluated in the same way as in Example 1 to find that L(100 h)/L(ini) was 92.8% (initial luminance L (ini)=1,290 cd/m²) and the organic light emitting apparatus had excellent drive and life characteristics, although they were slightly inferior to drive and life characteristics in Example 1. Further, the light emission state after leaving at a temperature of 80° C. and a humidity of 80% for 1,000 hours was the same as in the case of before leaving.

### Example 4

An organic light emitting apparatus was produced in the same way as in Example 1 using the device substrate used in Example 1 as it was except that the pressure during the treatment before the formation of an organic EL layer was 10 Pa, gas to be introduced was oxygen having 99.9% purity, an introduction flow rate was 0.5 slm, and a UV-light irradiation time was 20 minutes.

The obtained organic light emitting apparatus was evaluated in the same way as in Example 1 to find that L(100 h)/L(ini) was 91.6% (initial luminance L (ini)=1,210 cd/m²) and the organic light emitting apparatus had drive and life characteristics which are not problematic in practical use, although they were slightly inferior to drive and life characteristics in other examples. Further, the light emission state after leaving at a temperature of 80° C. and a humidity of 80% for 1,000 hours was the same as in the case of before leaving.

### Comparative Example 1

An organic light emitting apparatus was produced in the same way as in Example 1 using the device substrate used in Example 1 as it was except that the pressure during the treatment before the formation of an organic EL layer was 101,300 Pa (atmospheric pressure).

The obtained organic light emitting apparatus was evaluated in the same way as in Example 1 to find that L(100 h)/L(ini) was 90.5% (initial luminance L (ini)=1,300 cd/m²) and the drive and life characteristics of the organic light emitting apparatus were inferior to those in the above examples. Further, after the organic light emitting apparatus was left at a temperature of 80° C. and a humidity of 80% for 1,000 hours, it was observed that the peripheral portions in pixels were darkened, which was not observed before leaving.

### Comparative Example 2

An organic light emitting apparatus was produced in the same way as in Example 1 using the device substrate used in Example 1 as it was except that the pressure during the treatment before the formation of an organic EL layer was 5 Pa, gas to be introduced was oxygen having 99.9% purity, an introduction flow rate was 0.05 slm, and a UV-light irradiation time was 20 minutes.

The obtained organic light emitting apparatus was evaluated in the same way as in Example 1 to find that L(100 h)/L(ini) was 10.5% (initial luminance L(ini)=1,200 cd/m²) and the drive and life characteristics of the organic light emitting apparatus were poor. Further, after the organic light emitting apparatus was left at a temperature of 80° C. and a humidity of 80% for 1,000 hours, it was observed that the entire light emitting portion was darkened.

### Comparative Example 3

An organic light emitting apparatus was produced in the same way as in Example 1 using the device substrate used in Example 2 as it was except that the pressure during the treatment before the formation of an organic EL layer was 101,300 Pa (atmospheric pressure).

The obtained organic light emitting apparatus was evaluated in the same way as in Example 1 to find that L(100 h)/L(ini) was 89.0% (initial luminance L (ini)=1,300 cd/m²) and the drive and life characteristics of the organic light emitting apparatus were inferior to those in the above examples. Further, after the organic light emitting apparatus was left at a temperature of 80° C. and a humidity of 80% for 1,000 hours, it was observed that the peripheral portions in pixels were darkened, which was not observed before leaving.

TABLE 1

| | UV ozone treatment condition | | | | | |
|---|---|---|---|---|---|---|
| | | | Introduction | Irradiation | | After leaving at |
| | Ambient | Gas to be | amount | time | L(100h)/L(ini) | 80° C. and 80% |
| | pressure | introduced | (slm) | (min) | at 100 mA/cm² | for 1,000 hours |
| Example 1 | 1,000 | Dry air | 10 | 10 | 95 | Uniform |
| Example 2 | 100 | DRY air | 10 | 10 | 94.5 | Uniform |
| Example 3 | 10,000 | Dry air | 10 | 10 | 92.8 | Uniform |
| Example 4 | 10 | Oxygen | 0.5 | 20 | 91.6 | Uniform |
| Comparative | 101,300 | Dry air | 10 | 10 | 90.5 | Periphery |
| Example 1 | | | | | | darkened |
| Comparative | 5 | Oxygen | 0.05 | 20 | 10.5 | Entire portion |
| Example 2 | | | | | | darkened |
| Comparative | 101,300 | Dry air | 10 | 10 | 89.0 | Periphery |
| Example 3 | | | | | | darkened |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2007-118217, filed Apr. 27, 2007, and No. 2008-057471, filed March 7, 2008, which are hereby incorporated by reference herein in its entirety.

What is claimed is:

1. A method of producing an organic light emitting apparatus including a substrate, an organic light emitting device formed on the substrate, and a device separating film formed on a periphery of the organic light emitting device,
the organic light emitting device including a lower electrode, an organic compound layer, and an upper electrode from the substrate side in the stated order,
the method comprising:
cleaning a substrate having at least the lower electrode and the device separating film formed thereon by irradiating the substrate with UV-light while introducing gas containing at least oxygen into an atmosphere and exhausting the gas under a pressure in a range of 10 Pa or more to 10,000 Pa or less;
forming an organic compound layer on the cleaned lower electrode; and
forming an upper electrode on the organic compound layer.

2. The method according to claim 1, further comprising subjecting the substrate having at least the lower electrode and the device separating film formed thereon to dehydration by heating under vacuum, wherein:
the cleaning comprises cleaning the substrate subjected to the dehydration by heating; and
the forming the organic compound layer comprises forming an organic compound layer on the lower electrode on the cleaned substrate under vacuum.

3. The method according to claim 1, wherein the lower electrode is an anode.
